(19) United States
(12) Patent Application Publication
(10) Pub. No.: US 2025/0349816 A1
(43) Pub. Date: Nov. 13, 2025

(54) SEMICONDUCTOR PACKAGE WITH CARRIER SUPPORT STRUCTURE

(71) Applicant: Infineon Technologies Austria AG, Villach (AT)

(72) Inventors: Joon Dong Kim, Namdong-gu (KR); Kyoung Min Song, Cheonan-si (KR); Kye Ryung Kim, Yeonsu-gu (KR)

(21) Appl. No.: 18/658,755

(22) Filed: May 8, 2024

(51) Int. Cl. H01L 25/00; H01L 21/48; H01L 23/495; H01L 23/498; H01L 25/16

(52) U.S. Cl. CPC H01L 25/50; H01L 21/4853; H01L 23/49531; H01L 23/49575; H01L 23/49861; H01L 25/162

(57) ABSTRACT

A method of forming a semiconductor package includes providing a lead frame that comprises a plurality of leads connected with a peripheral structure; providing a plurality of die pads each having a power switching device mounted thereon; providing a first circuit carrier with a controller device mounted thereon, the controller device being configured to control a switching operation of the power switching devices; forming a mechanical connection between the first circuit carrier and the lead frame; and performing an encapsulation process to form an electrically insulating encapsulant body that encapsulates the power switching devices and the controller device, wherein the first circuit carrier is physically supported by the mechanical connection prior to performing the encapsulation process, and wherein forming the mechanical connection comprises an electrical interconnection processing technique.

### BACKGROUND

Many different applications such as automotive and industrial applications utilize power modules that comprise multiple power devices in a single package or housing. Power modules may include power conversion circuits such as single and multi-phase half-wave rectifiers, single and multi-phase full-wave rectifiers, voltage regulators, inverters, etc. Modern power modules are designed for minimal power losses and can improve the energy efficiency of a power system. Power modules can form part of power efficient solutions to reduce or prevent anthropogenic emissions of greenhouse gases. For instance, hybrid electric vehicles (HEVs) or electric vehicles (EVs) utilize power modules to perform power conversion, inversion, switching, etc., in a power efficient manner. Integrated power modules (IPMs), also referred to as intelligent power modules, include both power electronic circuitry and the logic circuitry for controlling operation of the power electronic circuitry. It is desirable to produce integrated power modules at lower cost and higher reliability.

### SUMMARY

Those skilled in the art will recognize additional features and advantages upon reading the following detailed description, and upon viewing the accompanying drawings.

A method of forming a semiconductor package is disclosed. According to an embodiment, the method comprises providing a lead frame that comprises a plurality of leads connected with a peripheral structure; providing a plurality of die pads each having a power switching device mounted thereon; providing a first circuit carrier with a controller device mounted thereon, the controller device being configured to control a switching operation of the power switching devices; forming a mechanical connection between the first circuit carrier and the lead frame; and performing an encapsulation process to form an electrically insulating encapsulant body that encapsulates the power switching devices and the controller device, wherein the first circuit carrier is physically supported by the mechanical connection prior to performing the encapsulation process, and wherein forming the mechanical connection comprises an electrical interconnection processing technique.

A semiconductor package is disclosed. According to an embodiment, the semiconductor package comprises a lead frame that comprises a plurality of leads; a plurality of die pads each having a power switching device mounted thereon; a first circuit carrier with a controller device mounted thereon, the controller device being configured to control a switching operation of the power switching devices; a mechanical connection with the first circuit carrier; and an electrically insulating encapsulant body that encapsulates the power switching devices and the controller device, wherein the mechanical connection is electrically inactive, and wherein the mechanical connection comprises one or more of: an attachable metal element and an electrically conductive adhesive.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates an assembly for forming a semiconductor package, according to an embodiment.

FIG. 2 illustrates an encapsulation step for forming a semiconductor package, according to an embodiment.

FIG. 3 illustrates a semiconductor package after encapsulation and lead trimming, according to an embodiment.

FIG. 4, which includes FIGS. 4A, 4B, 4C, 4D and 4E, illustrates various techniques for forming a mechanical connection between the semiconductor package and the lead frame, according to an embodiment.

FIG. 5 illustrates an assembly for forming a semiconductor package, according to an embodiment.

FIG. 6 illustrates an assembly for forming a semiconductor package, according to an embodiment.

### DETAILED DESCRIPTION

Embodiments of a semiconductor package and corresponding method for forming a semiconductor package are described herein. The semiconductor package is configured as an integrated power module with power switching devices and a controller device that is configured to control the switching of the power switching devices. The semiconductor package is formed from a package assembly with a dedicated circuit carrier that accommodates the controller device and the electrical interconnections with the controller device. The semiconductor package is formed by an encapsulation process whereby the lead frame and the circuit carrier are placed within a mold injection tool. This technique requires the circuit carrier to be physically supported before the encapsulation process until the encapsulation material hardens. The embodiments disclosed herein advantageously utilize an electrical interconnection processing technique to form a mechanical connection between the circuit carrier and the lead frame, thereby providing mechanical support of the circuit carrier before and during the encapsulation process. These electrical interconnection processing techniques are the same techniques that are typically used to form electrical connections. As a result, there is no need for a dedicated processing step and/or machine tooling to create the mechanical support between the circuit carrier and the lead frame. Moreover, the electrical interconnection processing techniques form stable mechanical connections at low expense and with high reliability.

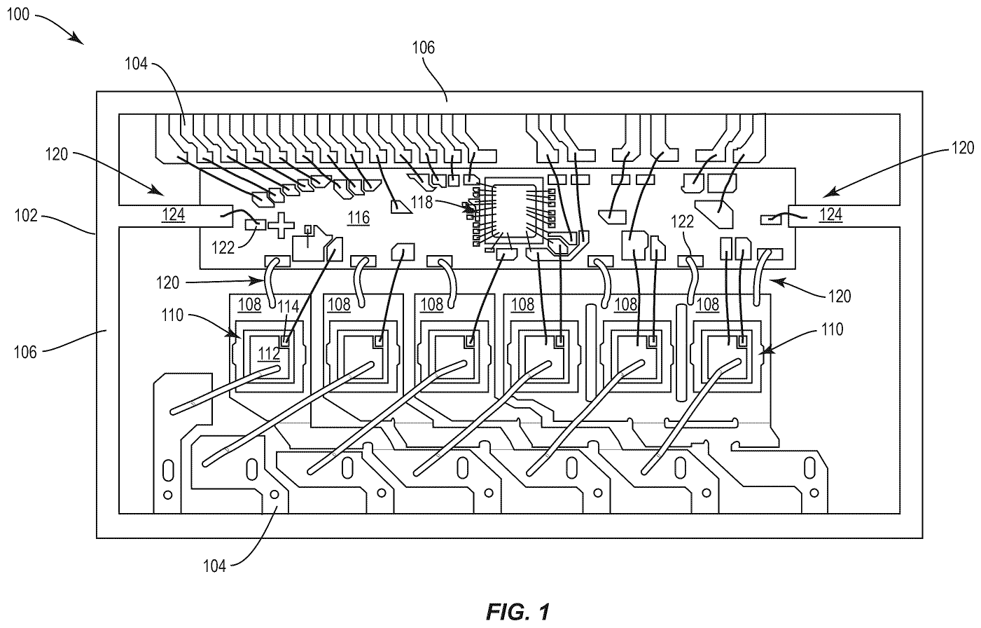

Referring to FIG. 1, an assembly 100 for forming a semiconductor package 200 is shown, according to an embodiment. The semiconductor package 200 comprises a lead frame 102 that comprises a plurality of leads 104 connected with a peripheral structure 106. The peripheral structure 106 forms an enclosed shape around a central region of the lead frame 102. Each of the leads 104 extend away from the central region of the lead frame 102 and connect with the peripheral structure 106. The lead frame 102 is formed from an electrically conductive metal, such as copper, nickel, aluminum, palladium, gold, and alloys or combinations thereof. The lead frame 102 can be provided from a substantially uniform thickness sheet of metal and the geometric features of the lead frame 102 can be created by metal processing techniques, e.g., stamping, punching, etching, etc. The lead frame 102 may comprise a core metal region with one or more layers or coatings, e.g., adhesion promotion layers, anticorrosion layers, etc.

The assembly 100 comprises a plurality of die pads 108 the that are used to accommodate the mounting of power switching devices 110 thereon. In the depicted embodiment, the plurality of die pads 108 is provided by the lead frame 102. That is, the lead frame 102 itself is used to accommodate the mounting of the power switching devices 110 thereon. The lead frame 102 is configured such that each die pad 108 is connected with the peripheral structure 106. Specifically, each die pad 108 is connected with one of the leads 104, which in turn is connected with the peripheral structure 106. In the depicted embodiment, the connections between the die pads 108 and the leads 104 are provided by recessed sections of the lead frame 102 that are vertically offset from the die pads 108 and the leads 104.

The power switching devices 110 are discrete transistor dies that are rated to control large voltages and currents, e.g., voltages of at least 100 V (volts), and more typically voltages of 600 V, 1200 V or more and/or currents of least 1 A, and more typically currents of 10 A, 50 A, 100 A or more. Examples of these devices include MOSFETs (Metal Oxide Semiconductor Field Effect Transistors), IGBTs (Insulated Gate Bipolar Transistors), and HEMTs (High Electron Mobility Transistors). As shown, the power switching devices 110 are configured as vertical devices, with a main surface comprising a first load terminal 112 (e.g., source, drain, collector, emitter, etc.) and a gate terminal 114 facing away from the respective die pad 108, and a rear surface comprising a second load terminal (e.g., the opposite one of the source, drain, collector, emitter, etc.) facing the respective die pad 108. In a commonly known manner, the power switching devices 110 are configured to control a conductive connection between the first load terminal 112 and the second load terminal via the gate terminal 114.

The assembly 100 further comprises a first circuit carrier 116 arranged within the central opening of the peripheral structure 106. The first circuit carrier 116 is a separate structure from the structure which provides the die pads 108 that are used to accommodate the mounting of power switching devices 110 thereon. Generally speaking, the first circuit carrier 116 can be any type of electronics carrier. According to an embodiment, the first circuit carrier 116 is a PCB.

A controller device 118 is mounted on the first circuit carrier 116. The controller device 118 is configured to control the switching operation of the power switching devices 110. The controller device 118 may be a logic device. For example, the controller device 118 may be a silicon-based logic die. The controller device 118 may be a so-called surface mount device, wherein leads of the controller device 118 are mounted on and form direct electrical connections with the first circuit carrier 116. Alternatively, the controller device 118 may be connected to the circuit carrier using interconnect elements (e.g., bond wires) at an upper side of the controller device 118 that are connected with the circuit board, wherein the lower side of the controller device 118 is affixed, e.g., using an adhesive.

The assembly 100 comprises the following electrical connections. A group of the leads 104 is electrically connected with input terminals of the controller device 118. Output terminals of the controller device 118 are electrically connected with the gate terminals 114 of the power switching devices 110. In each case, these electrical connections are effectuated by electrical interconnect elements (bond wires as shown) and conductive tracks in the first circuit carrier 116. The first load terminals 112 of the power switching devices 110 are electrically connected with the respective die pad, e.g., by a conductive adhesive such as solder, sinter, etc. In turn, each one of the die pads 108 is electrically connected with one of the leads 104 by the recessed sections of the lead frame 102, as described above. The first load terminals 112 of the power switching devices 110 are electrically connected with landing pad sections of the lead frame 102, which in turn are electrically connected with one of the leads 104. These electrical connections may be effectuated by electrical interconnect elements (e.g., bond wires) as shown.

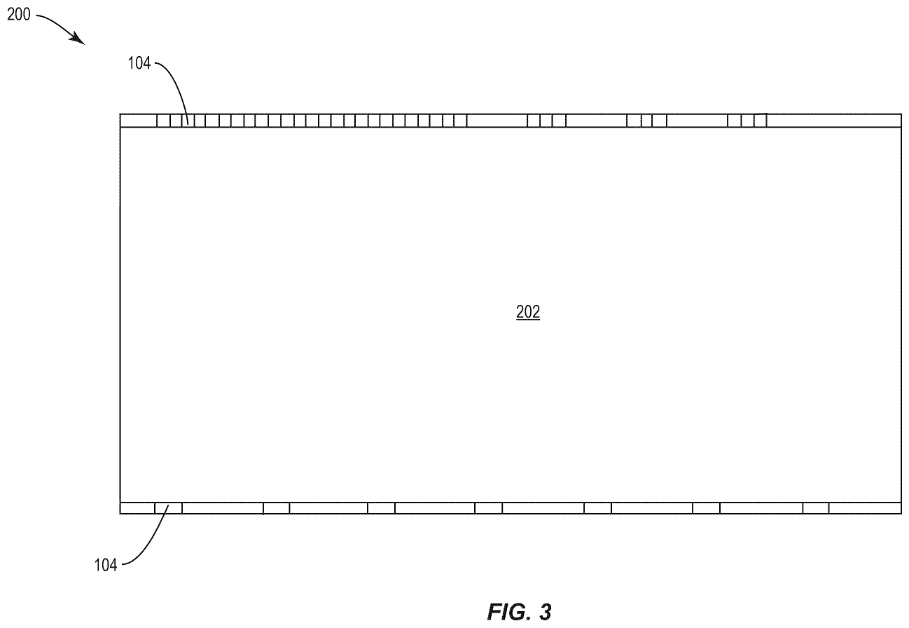

The semiconductor package 200 (shown in FIG. 3) formed by the assembly 100 is a so-called integrated power module (IPM), which refers to a type of package that includes both power electronic circuitry and the logic circuitry for controlling operation of the power electronic circuitry. Examples of the power circuits employed by these modules include single and multi-phase half-wave rectifiers, single and multi-phase full-wave rectifiers, voltage regulators, etc. In the depicted embodiment, the power switching devices 110 are implemented in a half-bridge circuit configuration. A half-bridge circuit refers to one type of circuit topology that is used in a power conversion circuit, such as a DC to DC converter, DC to AC converter, etc. A half-bridge circuit comprises a high-side switch connected in series with a low-side switch. The control terminals of the high-side switch and the low-side switch (e.g., the gate terminals 114) can be switched by the controller device 118 according to a power control scheme (e.g., pulse width modulation) to produce a desired voltage and frequency at the output of the half-bridge circuit. In the depicted embodiment, the leftmost three leads 104 connected with the first load terminals 112 of the three power switching devices 110 on the left side of the figure may be used to provide a fixed high voltage connection for the high-side switches, the rightmost lead 104 connected with the second load terminals of the three power switching devices 110 on the right side of the figure may be used to provide a second fixed voltage connection for the low-side switches, and the central three leads 104 in between the leftmost three leads 104 and the rightmost lead 104 that are each connected to the first load terminal 112 of one power switching device 110 and the second load terminal of another power switching device 110 may form the phase connections of the half-bridge circuit.

Before the encapsulation process, the assembly 100 comprising the lead frame 102 and the first circuit carrier 116 may be provided on a temporary carrier, such as a panel. The first circuit carrier 116 may be initially provided with the controller device 118 mounted thereon. Alternatively, the first circuit carrier 116 may be provided on the temporary carrier and subsequently the controller device 118 may be mounted thereon. The power switching devices 110 may be mounted on each of the die pads 108. Mounting the power switching devices 110 may comprise providing conductive adhesive, e.g., solder, between the second load terminals of the power switching devices 110 and the die pads 108, and performing an annealing step, e.g., solder reflow, as needed. Subsequently, the electrical interconnections of the semiconductor package 200 assembly 100 may be performed. The electrical interconnections may be formed by an electrical interconnection processing technique, e.g., wire bonding, soldering, etc. In the depicted embodiment, each of the electrical interconnections are effectuated using bond wires. Alternatively, other types of electrical interconnect elements such as metal clips and ribbons may be used instead.

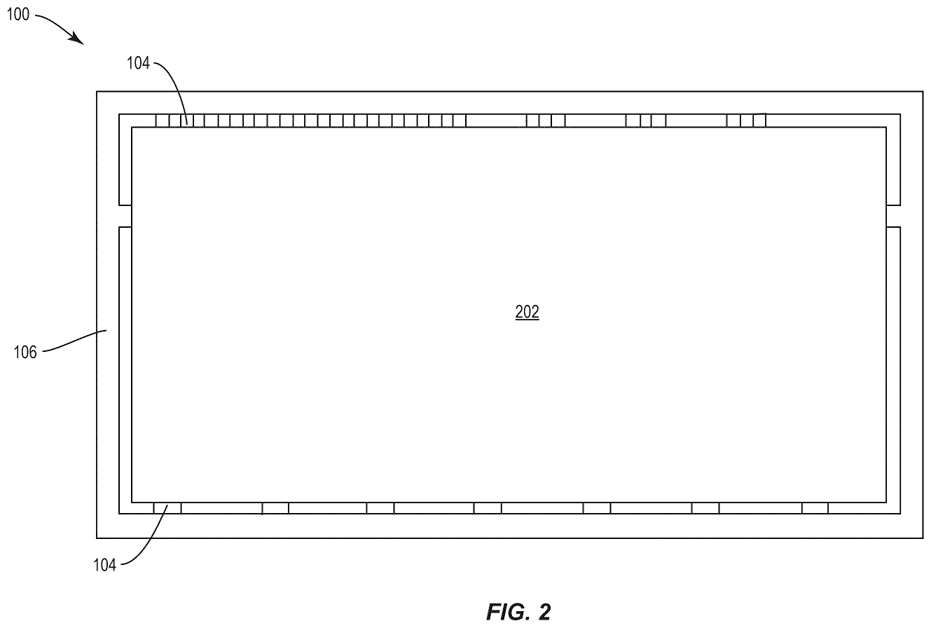

Referring to FIG. 2, the assembly 100 is shown after performing an encapsulation process. The encapsulation process forms an electrically insulating encapsulant body 202 that encapsulates the power switching devices 110 and the controller device 118. The encapsulation process may comprise an injection molding or compression molding technique wherein the assembly 100 is arranged within the volume of a mold chamber and liquified molding compound is flowed into the mold chamber and subsequently hardened by a curing process. The encapsulation material may include a mold compound, epoxy resin, polyimide, etc.

Referring to FIG. 3, a singulated semiconductor package 200 is shown, according to an embodiment. The singulated semiconductor package 200 is created by performing a lead trimming process to detach each of the leads 104 from the peripheral structure 106, e.g., by mechanical cutting, laser cutting, etching, etc., thereby creating individual leads 104. Although the figures depict a single semiconductor package 200, multiple semiconductor packages 200 may be produced simultaneously, wherein the lead frame 102 represents one unit cell that is repeated multiple times.

Referring again to FIG. 1, the assembly 100 comprises a plurality of mechanical connections 120 between the first circuit carrier 116 and the peripheral structure 106. These mechanical connections 120 are used to maintain the position of the first circuit carrier 116 during the encapsulation process. In more detail, after the mounting of the dies and formation of the electrical interconnections, the semiconductor package 200 assembly 100 is transferred from the temporary carrier to a molding tool, whereby the molding process is performed. At this time, the first circuit carrier 116 must be suspended in place until the encapsulant material that forms the encapsulant body 202 is formed and hardened, at which time the encapsulated features are held in place by the encapsulant. Prior to the encapsulation process, the first circuit carrier 116 is physically supported by the mechanical connections 120. The mechanical connections 120 may support substantially all of the weight of the first circuit carrier 116 at this time. In the depicted embodiment, the bond wire connections between the group of the leads 104 that are electrically connected with input terminals of the controller device 118 may provide a small degree of mechanical support. However, these bond wires are unable to support the full weight of the first circuit carrier 116 and thus the mechanical connections 120 are necessary to provide a substantial degree of mechanical support.

According to an embodiment, the mechanical connections 120 are formed by an electrical interconnection processing technique. As used herein, the term “electrical interconnection processing technique” refers to a technique that is used to form an electrical connection between the elements of a semiconductor package 200, e.g., an electrical connection between two bond pads, e.g., from a semiconductor device, passive device, circuit carrier, lead frame, etc. Examples of electrical interconnection processing techniques include techniques that affix an attachable metal element between two conductive bond pads, e.g., wire bonding, ribbon formation, clip attachment, etc. Additional examples of electrical interconnection processing techniques include techniques that form an electrically conductive adhesive, e.g., soldering, sintering, gluing, etc.

According to an embodiment, at least some of the mechanical connections 120 are electrically inactive. That is, these mechanical connections 120 do not conduct any electrical current and do not form a signal connection during operation of the semiconductor package 200. In this case, even though the mechanical connections 120 may be formed by an electrical interconnection processing technique, the features forming the mechanical connection are rendered electrically floating. To this end, the first circuit carrier 116 may comprise electrically isolated bond pads 122 disposed on the upper side of the first circuit carrier 116. These electrically isolated bond pads 122 are isolated from other signal connections by the insulating part of the first circuit carrier 116.

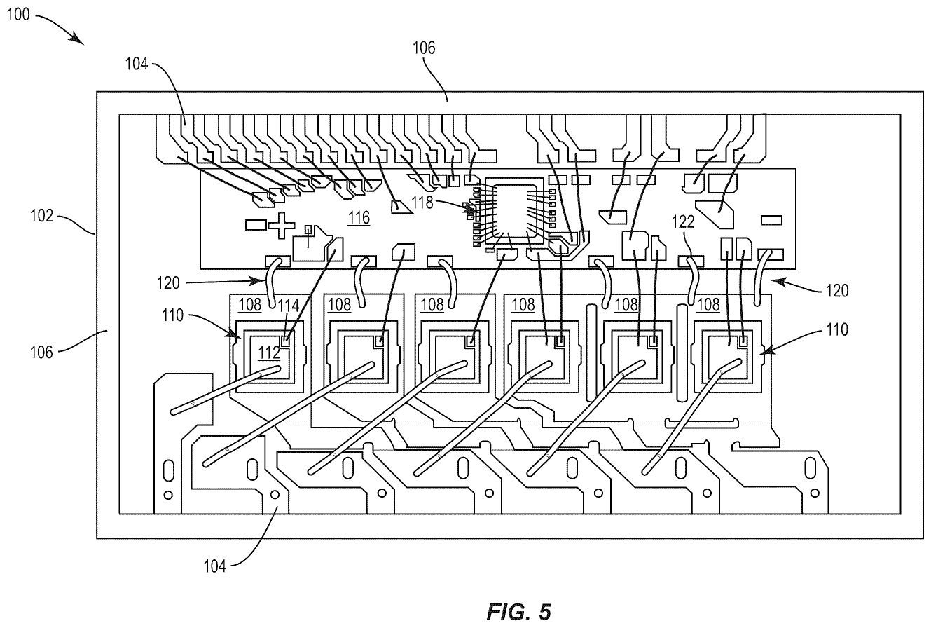

In the depicted embodiment, some of the mechanical connections 120 are provided by mechanical support posts 124 that are connected with the peripheral structure 106 of the lead frame 102. According to an embodiment, the lead frame 102 comprises the mechanical support posts 124. That is, the mechanical support posts 124 form constituent parts of the lead frame 102 itself. The lead frame 102 is configured such that the mechanical support posts 124 extend over outer edge sides of the first circuit carrier 116 when the lead frame 102 arranged on the temporary carrier. The mechanical support posts 124 thus provides a surface from which the first circuit carrier 116 may be physically coupled with the with the peripheral structure 106 of the lead frame 102. The mechanical support posts 124 can be directly attached with the first circuit carrier 116 using the electrical interconnection processing technique. As shown, the mechanical support posts 124 are directly attached to the with the first circuit carrier 116 by a bond wire connection. Various specific embodiments of the connections between the mechanical support posts 124 and the first circuit carrier 116 are described in further detail below with reference to FIG. 5. After encapsulation, the mechanical support posts 124 may be trimmed, e.g., in a similar manner or common step as the lead trimming process, so that the outside of the encapsulant body 202 comprises outer faces with severed ends of the mechanical support posts 124 that are coplanar or close to coplanar with the outer faces.

In the depicted embodiment, some of the mechanical connections 120 are provided by direct connections between the die pads 108 from the lead frame 102 and the first circuit carrier 116. These direct connections are also provided by using an electrical interconnection processing technique. In the depicted embodiment, the mechanical connections 120 that directly connect the die pads 108 with the first circuit carrier 116 are provided by bond wires. That is, the electrical interconnection processing technique used to form the mechanical connections 120 between the first circuit carrier 116 and the lead frame 102 is a wire bonding technique. These mechanical connections 120 between the die pads 108 from the lead frame 102 and the first circuit carrier 116 may be used to supplement the mechanical connections 120 provided by the mechanical support posts 124, thereby providing greater mechanical stability and distributing the weight of the first circuit carrier 116 across multiple support points.

In addition to the depicted embodiment, the mechanical connections 120 may be implemented in a variety of ways using electrical interconnection processing techniques. For example, instead of mechanical support posts 124 that are formed as dedicated parts of the lead frame 102, a separate interconnect element such as a metal clip may be attached to the peripheral structure 106, e.g., by soldering, welding, etc. Separately or in combination, instead of bond wires, different types of interconnect elements such as metal clips and ribbons may be to form the mechanical connections 120. Separately or in combination, electrically conductive adhesives may be used instead or in combination with the interconnect elements to form at least some of the mechanical connections 120.

According to an embodiment, at least some of the electrical interconnection processing techniques used to form the mechanical connections 120 are performed as part of a common process that is also used to form the active electrical interconnections of the device. That is, a single processing step may be performed using the same processing tools and/or electrical interconnect elements to form both active electrical interconnections and the mechanical connections 120. In one particular example of this, the mechanical connections 120 are formed by a wire bonding process that is also used to form the active electrical interconnections of the device. In particular, the wire bonding process for the active electrical interconnections that require the thickest and hence mechanically strongest bond wires. For instance, the bond wire connections between the first load terminals 112 of the power switching devices 110 and the lead frame 102 may be formed using relatively thick bond wires, e.g., bond wires with thickness of at least 50 μm, at least 100 μm, at least 150 μm, at least 200 μm, at least 250 μm, etc. For example, these bond wires have a thickness of between 200 μm and 300 μm, e.g., 250 μm in one particular embodiment.

Generally speaking, the number, location and properties of the mechanical connections 120 formed by electrical interconnection processing technique may be selected to meet the necessary structural requirements for supporting the first circuit carrier 116. For example, different numbers of the mechanical support posts 124, e.g., three, four, six, eight, etc. and corresponding connections may be used. Separately or in combination, different numbers of the electrical interconnect elements may be used.

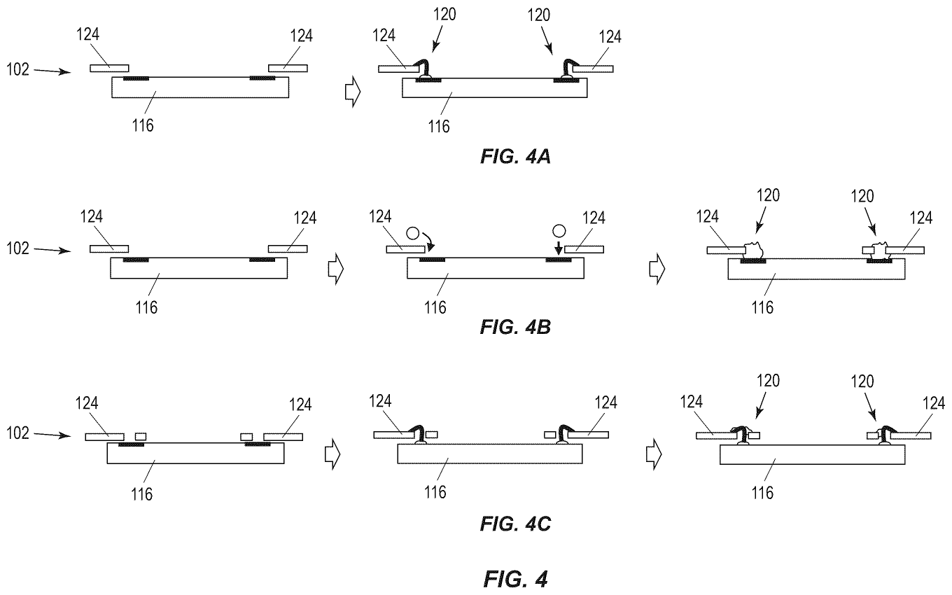

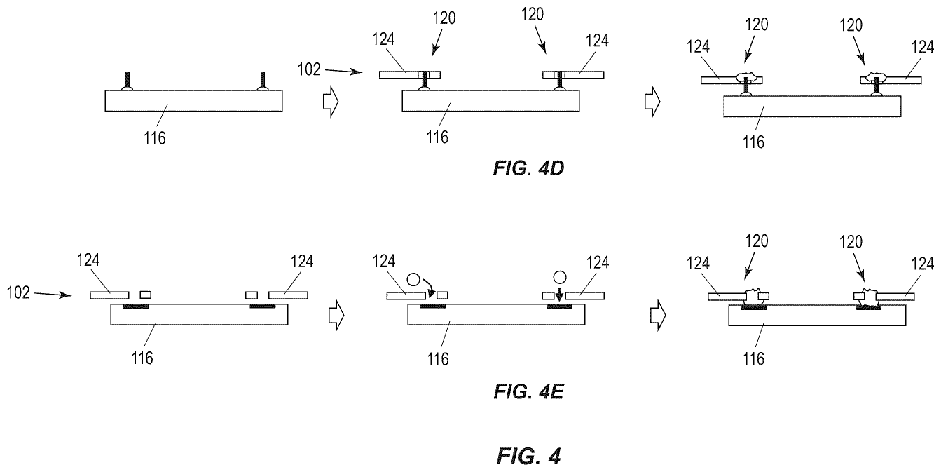

Referring to FIG. 4, various embodiments of the electrical interconnection processing techniques for forming the mechanical connections 120 are shown. In each case, a lead frame 102 comprising two of the mechanical support posts 124 is shown extending over the outer edge sides of the first circuit carrier 116. For the ease of illustration, other components of the assembly 100 including the peripheral structure 106 and the controller device 118 are omitted.

A first electrical interconnection processing technique for forming the mechanical connection is shown in FIG. 4A. In a first step of this technique, the first circuit carrier 116 is provided and the lead frame 102 is arranged such that the mechanical support posts 124 extend over the outer edge sides of the first circuit carrier 116. The lead frame 102 is configured such that there is a vertical offset between the upper surface of the first circuit carrier 116 and the mechanical support post with sufficient spacing to form a bond wire connection, e.g., between about 25 μm and 200 μm. In a second step of this technique, a wire bonding process is performed to form a bond wire between an upper side of the first circuit carrier 116 and the mechanical support post 124. The wire bonding process may be formed according to any of a variety of techniques that utilize mechanical pressure and/or heat to form a secure mechanical connection. For example, the wire bonding process may comprise a wedge-wedge process, a wedge-ball process (as shown), etc.

A second electrical interconnection processing technique for forming the mechanical connection is shown in FIG. 4B. In a first step of this technique, the first circuit carrier 116 is provided and the lead frame 102 is arranged such that the mechanical support posts 124 extend over the outer edge sides of the first circuit carrier 116 in a similar manner as described above. In a second step of this technique, an attachment material is provided. The attachment material may comprise any material that forms an adhesive connection, e.g., solder, sinter, glue, etc. In a third step of this technique, an attachment process is performed to directly attach the first circuit carrier 116 with the mechanical support posts 124 using the attachment material. This attachment process may comprise applying, pressure, time, etc., to induce reflow, curing, etc., as the case may be. As a result, the attachment material forms a stable mechanical connection.

A third electrical interconnection processing technique for forming the mechanical connection is shown in FIG. 4C. In a first step of this technique, the first circuit carrier 116 is provided and the lead frame 102 is arranged such that the mechanical support posts 124 extend over the outer edge sides of the first circuit carrier 116 in a similar manner as described above. In this case, the mechanical support posts 124 comprise a perforation, i.e., an opening through the thickness of the lead frame 102. The lead frame 102 is arranged such that these perforations extend over the upper side of the first circuit carrier 116. In a second step of this technique, a wire bonding process is performed to form bond wires between an upper side of the first circuit carrier 116 and the mechanical support posts 124. In this case, the bond wires are extended through the perforation. In a third step of this technique, an electrically conductive adhesive is provided within the perforation. The electrically conductive adhesive provides an additional mechanism to attach the bond wire with the mechanical support post, thereby enhancing the mechanical strength of the connection.

A fourth electrical interconnection processing technique for forming the mechanical connection is shown in FIG. 4D. In a first step of this technique, the vertical wire is formed on the upper surface of the first circuit carrier 116. The vertical wire may be a conductive pillar or other type of metal structure that is formed as a standalone structure. In a second step of this technique, the lead frame 102 is arranged such that the mechanical support posts 124 extend over the outer edge sides of the first circuit carrier 116 and such that the vertical wire extends through the perforation. In a third step of this technique, an electrically conductive adhesive is provided within the perforation. The electrically conductive adhesive secures the vertical wire with the mechanical support post.

A fifth electrical interconnection processing technique for forming the mechanical connection is shown in FIG. 4E. In a first step of this technique, the first circuit carrier 116 is provided and the lead frame 102 is arranged such that the mechanical support posts 124 extend over the outer edge sides of the first circuit carrier 116. In this case, the mechanical support posts 124 comprise a perforation. The lead frame 102 is arranged such that these perforations extend over the upper side of the first circuit carrier 116. In a second step of this technique, an attachment material is provided. In a third step of this technique, the attachment material is applied within the perforation and an attachment process is performed to directly attach the first circuit carrier 116 with the mechanical support post using the attachment material. This attachment process may comprise applying, pressure, time, etc., to induce reflow, curing, etc., as the case may be. As a result, the attachment material forms a stable mechanical connection.

Referring to FIG. 5, an assembly 100 for forming a semiconductor package 200 is shown, according to another embodiment. The assembly 100 of FIG. 5 is identical to that of FIG. 1, except that the mechanical support posts 124 that are attached with the peripheral structure 106 have been omitted. In this case, the mechanical connection between the circuit carrier and the lead frame 102 is provided by the direct connections between the die pads 108 from the lead frame 102 and the first circuit carrier 116, i.e., the bond wire connections that are electrically inactive and serve only as mechanical support. Similar to the embodiment described with reference to FIG. 1, some additional mechanical support may be provided by smaller bond wires that are connected between the first circuit carrier 116 and the group of leads 104 providing the input connections with the controller device 118. However, the bond wires connected between the die pads 108 and the first circuit carrier 116 may be configured to physically support a majority of the mechanical load. The thickness and number of the bond wires can be selected to create sufficient mechanical stability.

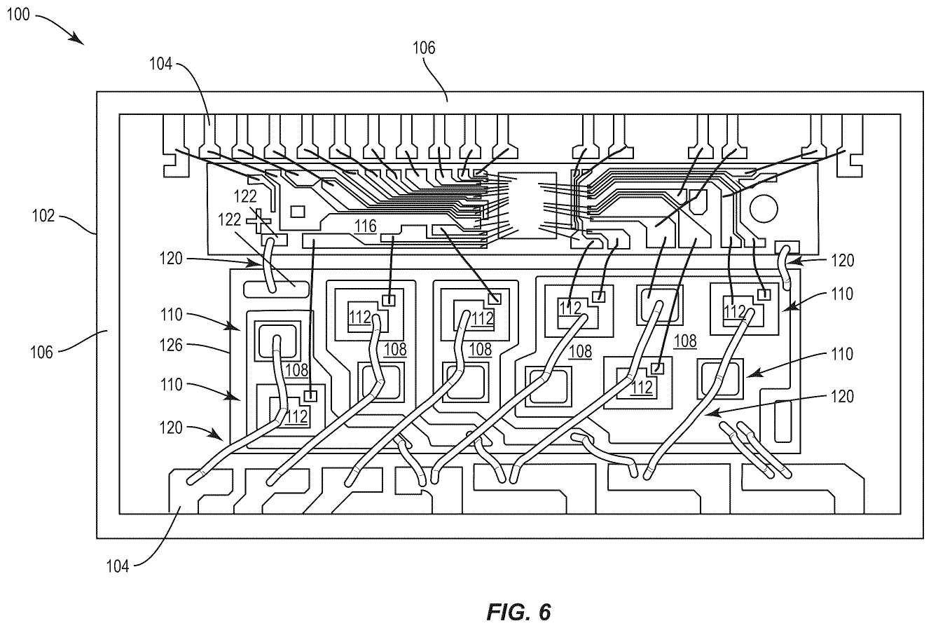

Referring to FIG. 6, an assembly 100 for forming a semiconductor package 200 is shown, according to another embodiment. In this case, the assembly 100 additionally comprises a second circuit carrier 126 adjacent to and spaced apart from the first circuit carrier 116. The plurality of die pads 108 that accommodate the mounting of the power switching devices 110 thereon is provided by the second circuit carrier 126. That is, the second circuit carrier 126 replaces the die pad portions of the lead frame 102 from the previous embodiment. The second circuit carrier 126 may be PCB or a power electronics carrier, such as a DCB substrate, a DAB substrate, or an AMB substrate, etc. As shown, the assembly 100 of FIG. 6 includes pairs of power switching devices 110 mounted adjacent to one and on a common die pad 108. Each pair of power switching devices 110 may correspond to a the high-side switch and low-side switch of a half bridge circuit.

In the embodiment of FIG. 6, each of the first circuit carrier 116 and the second circuit carrier 126 are mechanically connected with the peripheral structure 106 of the lead frame 102 by mechanical connections 120 that are formed by electrical interconnection processing techniques. In particular, the mechanical connection between the second circuit carrier 126 and the lead frame 102 is provided by a group of bond wires connected between the load terminals of the pairs of power switching devices 110 and the output leads 104. This group of bond wires may also provide the electrical connection between the leads 104 and the power switching devices 110, i.e., the phase connections for each half-bridge circuit. The first circuit carrier 116 is physically supported by a group of bond wires connected between the second circuit carrier 126 and the first circuit carrier 116. This group of bond wires provides physical support by virtue of their connection with the second circuit carrier 126. This, the first circuit carrier 116 is physically coupled to the lead frame 102 via the second circuit carrier 126. As shown, the second circuit carrier 126 may include electrically isolated bond pads 122 that accommodate the bond wires forming the mechanical connection, thereby maintaining these connections as electrically inactive.

Embodiments disclosed herein describe semiconductor devices, which may be referred to a semiconductor chip or semiconductor die. These semiconductor devices can comprise any of a wide variety of semiconductor materials including but not limited to elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum. These semiconductor devices can have a wide variety of device configurations including integrated device configurations and discrete device configurations. These semiconductor devices may be configured as a vertical device, which refers to a device that conducts a load current between opposite facing main and rear surfaces of the die. Alternatively, these semiconductor devices may be configured as a lateral device, which refers to a device that conducts a load current parallel to a main surface of the die.

The term “circuit carrier” as used herein intends to describe an electronics board that is configured to accommodate the mounting of electronic devices, e.g., semiconductor dies, passives, etc., thereon. A circuit carrier includes an electrically insulating substrate region and one or more metallization layers. The metallization layers may be structured into die pads 108, bond pads, and conductive tracks to facilitate electrical interconnection between the various devices mounted thereon and/or between the devices mounted thereon and an external device. Examples of circuit carriers include PCBs (printed circuit boards) and power electronics carriers, e.g., DCBs (Direct Copper Bonding substrates), DAB substrates (Direct Aluminum Bonding), and AMB substrates (Active Metal Brazing) substrate, etc. In the case of a PCB, the electrically insulating substrate portion of the circuit carrier may comprise laminate materials including prepreg materials, e.g., FR-4, FR-5, CEM-4, etc., and resin materials such as bismaleimide trazine (BT) resin. In the case of a power electronics carrier, the electrically insulating substrate portion of the circuit carrier may comprise a ceramic material such as Al₂O₃ (Alumina) AlN (Aluminium Nitride), etc. In either example, metallization layer or layers of the circuit carrier may be formed from conductive metals such as copper (Cu), aluminium (Al), nickel (Ni), silver (Ag), palladium (Pd) gold (Au), etc., and alloys or combinations thereof.

The term “electrical interconnect element” as used herein encompasses any electrically conductive element that can be connected between two conductive regions to complete an electrical interconnection between them. Examples of electrical interconnect elements include bond wires, ribbons and metal clips. In any of the embodiments, each of the electrical connections may be provided by a single electrical interconnect element or by a plurality of electrical interconnect elements forming a parallel connection.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although the present disclosure is not so limited, the following numbered examples demonstrate one or more aspects of the disclosure.

Example 1. A method of forming a semiconductor package, the method comprising: providing a lead frame that comprises a plurality of leads connected with a peripheral structure; providing a plurality of die pads each having a power switching device mounted thereon; providing a first circuit carrier with a controller device mounted thereon, the controller device being configured to control a switching operation of the power switching devices; forming a mechanical connection between the first circuit carrier and the lead frame; and performing an encapsulation process to form an electrically insulating encapsulant body that encapsulates the power switching devices and the controller device; wherein the first circuit carrier is physically supported by the mechanical connection prior to performing the encapsulation process, wherein forming the mechanical connection comprises an electrical interconnection processing technique.

Example 2. The method of example 1, wherein the mechanical connection is electrically inactive.

Example 3. The method of example 1, wherein the first circuit carrier is a printed circuit board, and wherein the mechanical connection is affixed to an electrically isolated bond pad disposed on an upper side of the a first circuit carrier.

Example 4. The method of example 1, wherein the electrical interconnection processing technique comprises one or more of: affixing an attachable metal element to one or both of the first circuit carrier and the lead frame; and applying an electrically conductive adhesive to one or both of the first circuit carrier and the lead frame.

Example 5. The method of example 4, wherein the electrical interconnection processing technique comprises affixing the attachable metal element to one or both of the first circuit carrier and the lead frame, and wherein the attachable metal element is a bond wire.

Example 6. The method of example 4, wherein the electrical interconnection processing technique comprises applying the electrically conductive adhesive to one or both of the first circuit carrier and the lead frame, and wherein the electrically conductive adhesive is a solder material.

Example 7. The method of example 4, wherein the lead frame comprises a mechanical support post, wherein the method comprises arranging the mechanical support post to extend over an outer edge side of the first circuit carrier, and wherein forming the mechanical connection comprises directly attaching the mechanical support post with the first circuit carrier using the electrical interconnection processing technique.

Example 8. The method of example 7, wherein directly attaching the mechanical support post to an upper side of the first circuit carrier comprises attaching a bond wire to the upper side of the first circuit carrier and the mechanical support post.

Example 9. The method of example 8, wherein directly attaching the mechanical support post to the upper side of the first circuit carrier further comprises soldering the bond wire to the upper side of the first circuit carrier and the mechanical support post.

Example 10. The method of example 7, wherein directly attaching the mechanical support post to an upper side of the first circuit carrier further comprises applying an electrically conductive adhesive between the upper side of the first circuit carrier and the mechanical support post.

Example 11. The method of example 7, wherein the mechanical support post comprises a perforation, and wherein the mechanical support post is arranged such that the perforation extends over an upper side of the first circuit carrier.

Example 12. The method of example 11, wherein forming the mechanical connection comprises attaching a bond wire to an upper side of the first circuit carrier and the mechanical support post, the bond wire being routed through the perforation.

Example 13. The method of example 11, wherein forming the mechanical connection comprises: forming a vertical wire on an upper side of the first circuit carrier; arranging the vertical wire within the perforation; and attaching the vertical wire to the mechanical support post by an electrically conductive adhesive.

Example 14. The method of example 11, wherein forming the mechanical connection comprises providing an electrically conductive adhesive within the perforation that directly attaches the mechanical support post with the first circuit carrier.

Example 15. The method of example 1, wherein the plurality of die pads is provided by the lead frame, wherein the lead frame is configured such that each of the die pads are connected with the peripheral structure.

Example 16. The method of example 15, wherein forming the mechanical connection between the first circuit carrier and the lead frame comprises attaching at least some of the die pads to the first circuit carrier using the electrical interconnection processing technique.

Example 17. The method of example 1, wherein the plurality of die pads is provided by a second circuit carrier, wherein the method comprises forming a second mechanical connection between the second circuit carrier and the lead frame.

Example 18. The method of example 17, wherein forming the mechanical connection between the first circuit carrier and the lead frame comprises attaching the second circuit carrier to the first circuit carrier using the electrical interconnection processing technique.

Example 19. A semiconductor package, comprising: a lead frame that comprises a plurality of leads; a plurality of die pads each having a power switching device mounted thereon; a first circuit carrier with a controller device mounted thereon, the controller device being configured to control a switching operation of the power switching devices; a mechanical connection with the first circuit carrier; and an electrically insulating encapsulant body that encapsulates the power switching devices and the controller device, wherein the mechanical connection is electrically inactive, and wherein the mechanical connection comprises one or more of: an attachable metal element and an electrically conductive adhesive.

Example 20. The semiconductor package of example 19, wherein the first circuit carrier is a printed circuit board, and wherein the mechanical connection is affixed to an electrically isolated bond pad disposed on an upper side of the first circuit carrier.

Example 21. The semiconductor package of example 19, wherein the lead frame further comprises a severed mechanical post, and wherein the severed mechanical post forms part of the mechanical connection.

Example 22. The semiconductor package of example 21, wherein the attachable metal element is a bond wire that is attached to an upper side of the first circuit carrier and the severed mechanical post.

Example 23. The semiconductor package of example 19, wherein the plurality of die pads is provided by the lead frame, and wherein at least some of the die pads are attached to the first circuit carrier by the mechanical connection.

Example 24. The semiconductor package of example 19, wherein the plurality of die pads is provided by a second circuit carrier, and wherein the second circuit carrier is attached to the first circuit carrier by the mechanical connection.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method of forming a semiconductor package, the method comprising:
providing a lead frame that comprises a plurality of leads connected with a peripheral structure;
providing a plurality of die pads each having a power switching device mounted thereon;
providing a first circuit carrier with a controller device mounted thereon, the controller device being configured to control a switching operation of the power switching devices;
forming a mechanical connection between the first circuit carrier and the lead frame; and
performing an encapsulation process to form an electrically insulating encapsulant body that encapsulates the power switching devices and the controller device;
wherein the first circuit carrier is physically supported by the mechanical connection prior to performing the encapsulation process,
wherein forming the mechanical connection comprises an electrical interconnection processing technique.

2. The method of claim 1, wherein the mechanical connection is electrically inactive.

3. The method of claim 1, wherein the first circuit carrier is a printed circuit board, and wherein the mechanical connection is affixed to an electrically isolated bond pad disposed on an upper side of the a first circuit carrier.

4. The method of claim 1, wherein the electrical interconnection processing technique comprises one or more of:
affixing an attachable metal element to one or both of the first circuit carrier and the lead frame; and
applying an electrically conductive adhesive to one or both of the first circuit carrier and the lead frame.

5. The method of claim 4, wherein the electrical interconnection processing technique comprises affixing the attachable metal element to one or both of the first circuit carrier and the lead frame, and wherein the attachable metal element is a bond wire.

6. The method of claim 4, wherein the electrical interconnection processing technique comprises applying the electrically conductive adhesive to one or both of the first circuit carrier and the lead frame, and wherein the electrically conductive adhesive is a solder material.

7. The method of claim 4, wherein the lead frame comprises a mechanical support post, wherein the method comprises arranging the mechanical support post to extend over an outer edge side of the first circuit carrier, and wherein forming the mechanical connection comprises directly attaching the mechanical support post with the first circuit carrier using the electrical interconnection processing technique.

8. The method of claim 7, wherein directly attaching the mechanical support post to an upper side of the first circuit carrier comprises attaching a bond wire to the upper side of the first circuit carrier and the mechanical support post.

9. The method of claim 8, wherein directly attaching the mechanical support post to the upper side of the first circuit carrier further comprises soldering the bond wire to the upper side of the first circuit carrier and the mechanical support post.

10. The method of claim 7, wherein directly attaching the mechanical support post to an upper side of the first circuit carrier further comprises applying an electrically conductive adhesive between the upper side of the first circuit carrier and the mechanical support post.

11. The method of claim 7, wherein the mechanical support post comprises a perforation, and wherein the mechanical support post is arranged such that the perforation extends over an upper side of the first circuit carrier.

12. The method of claim 11, wherein forming the mechanical connection comprises attaching a bond wire to an upper side of the first circuit carrier and the mechanical support post, the bond wire being routed through the perforation.

13. The method of claim 11, wherein forming the mechanical connection comprises:
forming a vertical wire on an upper side of the first circuit carrier;
arranging the vertical wire within the perforation; and
attaching the vertical wire to the mechanical support post by an electrically conductive adhesive.

14. The method of claim 11, wherein forming the mechanical connection comprises providing an electrically conductive adhesive within the perforation that directly attaches the mechanical support post with the first circuit carrier.

15. The method of claim 1, wherein the plurality of die pads is provided by the lead frame, wherein the lead frame is configured such that each of the die pads are connected with the peripheral structure.

16. The method of claim 15, wherein forming the mechanical connection between the first circuit carrier and the lead frame comprises attaching at least some of the die pads to the first circuit carrier using the electrical interconnection processing technique.

17. The method of claim 1, wherein the plurality of die pads is provided by a second circuit carrier, wherein the method comprises forming a second mechanical connection between the second circuit carrier and the lead frame.

18. The method of claim 17, wherein forming the mechanical connection between the first circuit carrier and the lead frame comprises attaching the second circuit carrier to the first circuit carrier using the electrical interconnection processing technique.

19. A semiconductor package, comprising:
a lead frame that comprises a plurality of leads;
a plurality of die pads each having a power switching device mounted thereon;
a first circuit carrier with a controller device mounted thereon, the controller device being configured to control a switching operation of the power switching devices;
a mechanical connection with the first circuit carrier; and
an electrically insulating encapsulant body that encapsulates the power switching devices and the controller device,
wherein the mechanical connection is electrically inactive, and
wherein the mechanical connection comprises one or more of: an attachable metal element and an electrically conductive adhesive.

20. The semiconductor package of claim 19, wherein the first circuit carrier is a printed circuit board, and wherein the mechanical connection is affixed to an electrically isolated bond pad disposed on an upper side of the first circuit carrier.

21. The semiconductor package of claim 19, wherein the lead frame further comprises a severed mechanical post, and wherein the severed mechanical post forms part of the mechanical connection.

22. The semiconductor package of claim 21, wherein the attachable metal element is a bond wire that is attached to an upper side of the first circuit carrier and the severed mechanical post.

23. The semiconductor package of claim 19, wherein the plurality of die pads is provided by the lead frame, and wherein at least some of the die pads are attached to the first circuit carrier by the mechanical connection.

24. The semiconductor package of claim 19, wherein the plurality of die pads is provided by a second circuit carrier, and wherein the second circuit carrier is attached to the first circuit carrier by the mechanical connection.
